(19) United States
(12) Patent Application Publication
(10) Pub. No.: US 2009/0032098 A1
(43) Pub. Date: Feb. 5, 2009

(54) Photovoltaic device having multilayer antireflective layer supported by front substrate

(75) Inventor: Yiwei Lu, Ann Arbor, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 11/882,759

(22) Filed: Aug. 3, 2007

(51) Int. Cl. H01L 31/04

(52) U.S. Cl. 136/257; 136/252; 136/256

(57) ABSTRACT

In certain embodiments of this invention, an improved multilayer anti-reflection (AR) coating is provided on the exterior surface of the front glass substrate of a photovoltaic device. This AR coating functions to reduce reflection of desirable wavelengths from the front glass substrate, thereby allowing more light within the desirable solar spectrum to pass through the incident glass substrate and reach the photovoltaic semiconductor film so that the photovoltaic device can operate more efficiently. Also, the AR coating can reduce the amount of undesirable light (e.g., at least some IR and/or UV radiation) which reaches the semiconductor film of the device. In certain example embodiments, the multilayer AR coating includes a plurality of pairs of alternating high refractive index and low refractive index layers.

This invention relates to a photovoltaic device including a multilayer antireflective (AR) coating supported by a front glass substrate of the device. The AR coating includes a plurality of different layers in certain example embodiments of this invention. In certain example embodiments, the AR coating includes alternating layers of high and low index (n) material(s).

### BACKGROUND OF THE INVENTION

Glass is desirable for numerous properties and applications, including optical clarity and overall visual appearance. For some example applications certain optical properties (e.g., light transmission, reflection and/or absorption) are desired to be optimized. For example, in certain example instances reduction of light reflection from the surface of a glass substrate (e.g., superstrate or any other type of glass substrate) is desirable for photovoltaic devices such as solar cells.

Solar cells/modules are known in the art. Glass is an integral part of many photovoltaic modules (e.g., solar cells), including both crystalline and thin film types. A solar cell/module may include, for example, a photoelectric transfer film made up of one or more semiconductor layers located between a pair of substrates. One or more of the substrates may be of glass. Example solar cells are disclosed in U.S. Pat. Nos. 4,510,344, 4,806,436, 6,506,622, and 5,977,477, the disclosures of which are hereby incorporated herein by reference.

Substrate(s) in a solar cell/module are sometimes made of glass. Incoming radiation passes through the incident glass substrate (or front glass substrate) of the solar cell before reaching the active layers (e.g., photoelectric transfer film such as a semiconductor) of the solar cell. It has been found that certain wavelengths are light are desirable in photovoltaic devices as they contribute to output power of the device, whereas other wavelengths (e.g., certain UV and/or IR wavelengths) are undesirable as they degrade performance of the device. Desirable wavelengths of light that are reflected by the incident glass substrate does not make its way into the active film of the photovoltaic device thereby resulting in a less efficient device. In other words, it would be desirable to decrease the amount of certain desirable types of radiation that is reflected by the incident substrate, thereby increasing the amount of desirable radiation that makes its way to the active semiconductor film of the solar cell. In particular, the power output of a solar cell or photovoltaic module is dependant upon the amount of desirable light, or number of photons, within a specific range of the solar spectrum that pass through the incident glass substrate and reach the photovoltaic semiconductor.

Thus, it will be appreciated that there exists a need in the art to provide a wavelength selective antireflective (AR) coating on a front substrate of a photovoltaic device that permits desirable wavelengths to pass therethrough and reach the active semiconductor film of the device, but which reflects at least some undesirable wavelengths such as certain UV and/or IR wavelengths which tend to degrade device performance. In other words, it would be desirable to provide an AR coating on the front substrate of a photovoltaic device which is capable of enhancing transmission in selected optical wavelengths that are desirable, while at the same time rejecting other wavelengths that are detrimental to performance of the photovoltaic device.

### BRIEF SUMMARY OF EXAMPLE EMBODIMENTS OF THE INVENTION

In certain example embodiments of this invention, an improved multilayer anti-reflection (AR) coating is provided on an incident glass substrate of a solar cell or the like. This AR coating functions to reduce reflection of desirable wavelengths from the front glass substrate, thereby allowing more light within the desirable solar spectrum to pass through the incident glass substrate and reach the photovoltaic semiconductor film so that the photovoltaic device can be more efficient.

In certain example embodiments, the multilayer AR coating includes a plurality of pairs of alternating high refractive index layers and low refractive index layers. In certain example embodiments, the high refractive index may be of or include titanium oxide (e.g., TiO₂ or other suitable stoichiometry), and the low refractive index layers may be of or include silicon oxide (e.g., SiO₂ or other suitable stoichiometry). It has surprisingly been found that such a multilayer AR coating is capable of enhancing transmission of selected wavelengths that are desirable (e.g., 450-1100 nm), while at the same time rejecting certain undesirable wavelengths (e.g., certain IR and/or UV wavelengths) that are detrimental to performance of the photovoltaic device. This can lead to overall better performance and improved efficiency of the photovoltaic device.

In certain example embodiments, there is provided a photovoltaic device comprising: a front glass substrate; a photovoltaic semiconductor film; and a multilayer anti-reflection coating provided on a light incident side of the front glass substrate, the anti-reflection coating comprising from the front glass substrate moving outwardly away from the semiconductor film, a first high index layer comprising an oxide of titanium, a first low index layer comprising an oxide of silicon, a second high index layer comprising an oxide of titanium, a second low index layer comprising an oxide of silicon, a third high index layer comprising an oxide of titanium, a third low index layer comprising an oxide of silicon, a fourth high index layer comprising an oxide of titanium, and a fourth low index layer comprising an oxide of silicon.

In other example embodiments of this invention, there is provided a photovoltaic device comprising: a front glass substrate; a photovoltaic semiconductor film; and a multilayer anti-reflection coating provided on a light incident side of the front glass substrate, the anti-reflection coating comprising from the front glass substrate moving outwardly away from the semiconductor film, a first high index layer, a first low index layer, a second high index layer, a second low index layer, a third high index layer, and a third low index layer.

### BRIEF DESCRIPTION OF THE DRAWINGS

FIG. 1 is a cross sectional view of a photovoltaic device including an example multilayer antireflective (AR) coating on the front substrate according to an example embodiment of this invention.

FIG. 2 is a chart comparing data of certain example embodiments of this invention with a photovoltaic device not including this invention, thereby illustrating example advantages associated with certain example embodiments of this invention.

FIG. 3 is a graph illustrating transmission and reflection spectra from a 3 mm thick clear soda lime glass substrate with and without an example multilayer AR coating according to an example embodiment of this invention on the incident surface thereof.

### DETAILED DESCRIPTION OF EXAMPLE EMBODIMENTS OF THE INVENTION

Referring now more particularly to the figures in which like reference numerals refer to like parts/layers in the several views.

Photovoltaic devices such as solar cells convert solar radiation into usable electrical energy. The energy conversion occurs typically as the result of the photovoltaic effect. Solar radiation (e.g., sunlight) impinging on a photovoltaic device and absorbed by an active region of semiconductor material (e.g., a semiconductor film including one or more semiconductor layers such as a-Si layers, the semiconductor sometimes being called an absorbing layer or film) generates electron-hole pairs in the active region. The electrons and holes may be separated by an electric field of a junction in the photovoltaic device. The separation of the electrons and holes by the junction results in the generation of an electric current and voltage. In certain example embodiments, the electrons flow toward the region of the semiconductor material having n-type conductivity, and holes flow toward the region of the semiconductor having p-type conductivity. Current can flow through an external circuit connecting the n-type region to the p-type region as light continues to generate electron-hole pairs in the photovoltaic device. In certain example embodiments, single junction amorphous silicon (a-Si) photovoltaic devices have a semiconductor film which includes three semiconductor layers. In particular, a p-layer, an n-layer and an i-layer which is intrinsic. The amorphous silicon film (which may include one or more layers such as p, n and i type layers) may be of hydrogenated amorphous silicon in certain instances, but may also be of or include hydrogenated amorphous silicon carbon or hydrogenated amorphous silicon germanium, or the like, in certain example embodiments of this invention. For example and without limitation, when a photon of light is absorbed in the i-layer it gives rise to a unit of electrical current (an electron-hole pair). The p and n-layers, which contain charged dopant ions, set up an electric field across the i-layer which draws the electric charge out of the i-layer and sends it to an optional external circuit where it can provide power for electrical components. It is noted that while certain example embodiments of this invention are directed toward thin film amorphous-silicon (a-Si) or crystalline silicon (c-Si) based photovoltaic devices (e.g., single-junction or micromorph types), this invention is not so limited and may be used in conjunction with other types of photovoltaic devices in certain instances including but not limited to devices including other types of semiconductor material, single or tandem thin-film solar cells, CdS and/or CdTe photovoltaic devices, polysilicon and/or microcrystalline photovoltaic devices, and the like.

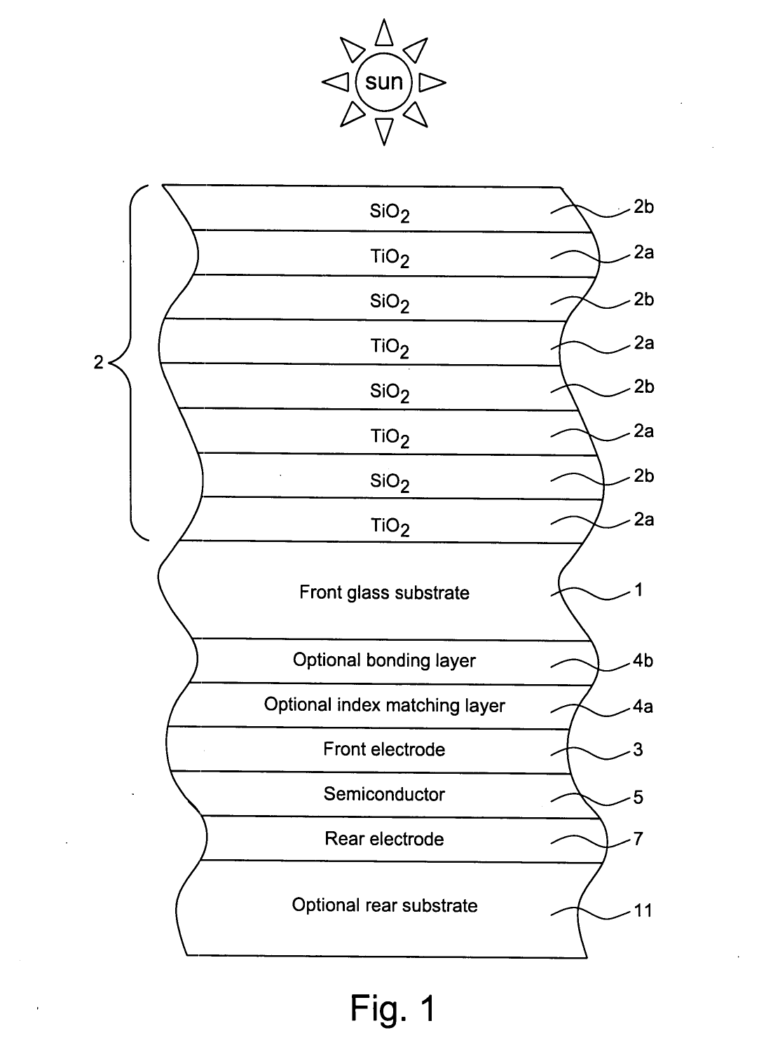

FIG. 1 is a cross sectional view of a photovoltaic device according to an example embodiment of this invention. The photovoltaic device includes transparent front or incident glass substrate 1 which may or may not have a textured surface(s), multilayer antireflective (AR) coating 2, front transparent electrode 3 (which may be multi-layered or single-layered) of a transparent conductive oxide (TCO) or the like, active and absorbing semiconductor film 5 of or including one or more semiconductor layers (such as pin, pn, pinpin tandem layer stacks, or the like), optional back electrode/contact and/or reflector 7 which may be of a TCO and/or metal(s), an optional polymer based encapsulant or adhesive (not shown) of a material such as ethyl vinyl acetate (EVA) or the like, and an optional rear substrate 11 of a material such as glass. The front glass substrate 1 is on the light incident side of the photovoltaic device. AR coating 2 is provided on the light incident side of the front glass substrate 1. Of course, other layer(s) which are not shown may also be provided in the device. Front glass substrate 1 and/or rear substrate 11 may be made of soda-lime-silica based glass in certain example embodiments of this invention; and may have low iron content and/or an antireflection coating thereon to optimize transmission in certain example instances. Glass 1 and/or 11 may or may not be thermally tempered in certain example embodiments of this invention. Additionally, it will be appreciated that the word “on” as used herein covers both a layer being directly on and indirectly on something, with other layers possibly being located therebetween.

In the FIG. 1 embodiment, the AR coating includes a plurality of layers 2a having a relatively high refractive index (n), and a plurality of layers 2b having a relatively low refractive index (n). Thus, high index layers 2a have a substantially higher (e.g., at least about 0.3 higher, more preferably at least about 0.5 higher, even more preferably at least about 0.7 or 0.9 higher, and possibly at least about 1.0 higher) refractive index (n) than do low index layers 2b. In certain example embodiments, there may be four pairs of high/low index layers stacked on top of one another, as in the FIG. 1 embodiment (a pair is made up of a set of 2a and 2b). Alternatively, there may three of five such pairs of high/low index layers in other example embodiments of this invention.

In certain example embodiments of this invention, the high index layers 2a may have a refractive index (n) of at least about 1.95, more preferably at least about 2.0, more preferably at least about 2.1, even more preferably at least about 2.2, and possibly at least about 2.3 or at least about 2.4. An example material for the high index layers 2a is an oxide of titanium such as TiOₓ, where x is from about 1.8 to 2.0, more preferably from about 1.9 to 2.0 and most preferably about 2.0). The high index layers may or may not be all made of the same material. In certain example embodiments of this invention, the low index layers 2b may have a refractive index of no more than about 1.8, more preferably no more than about 1.7, even more preferably no more than about 1.6, and possibly no more than about 1.5, and sometimes no more than about 1.46. An example material for the low index layers 2b is an oxide of Si such as SiOₓ, where x is from about 1.8 to 2.0, more preferably from about 1.95 to 2.0 and most preferably about 2.0. Silicon oxynitride may also be used for one or more of the low index layers 2b in certain example instances. The low index layer(s) 2b may optionally be doped with a metal such as Al or the like in certain example embodiments. The low index layers may or may not be all made of the same material. The layers 2a and 2b may be deposited on the glass substrate 1 in any suitable manner. For example, these layers may be deposited by sputtering in certain example embodiments.

The FIG. 1 example embodiment of this invention thus relates to an eight-layered antireflection coating 2 designed to improve the efficiency of solar photovoltaic devices by enhancing light transmission that contributes to solar cell output power, and, at the same time, rejecting certain UV and/or IR that degrade cell performance. The antireflection coating 2 is of alternate high/low index materials (2a, 2b, 2a, 2b, 2a, 2b, etc.). It has surprisingly been found that this multilayer AR coating has less than about 2% absorption loss, more preferably less than about 1% absorption loss, in the desirable wavelength range from 450 to 1100 nm (or alternative in the desirable range of 400-1100 nm). The enhanced transmission range (bandwidth) can be controlled by the thickness of each individual layer of the coating 2 and/or the ratio of high and low indices.

It is possible that other layer(s) (not shown) may be provided between the coating 2 and the substrate 1 in certain example embodiments. It is also possible that other layer(s) may be provided between the layers 2a, 2b illustrated in FIG. 1 in certain example embodiments of this invention.

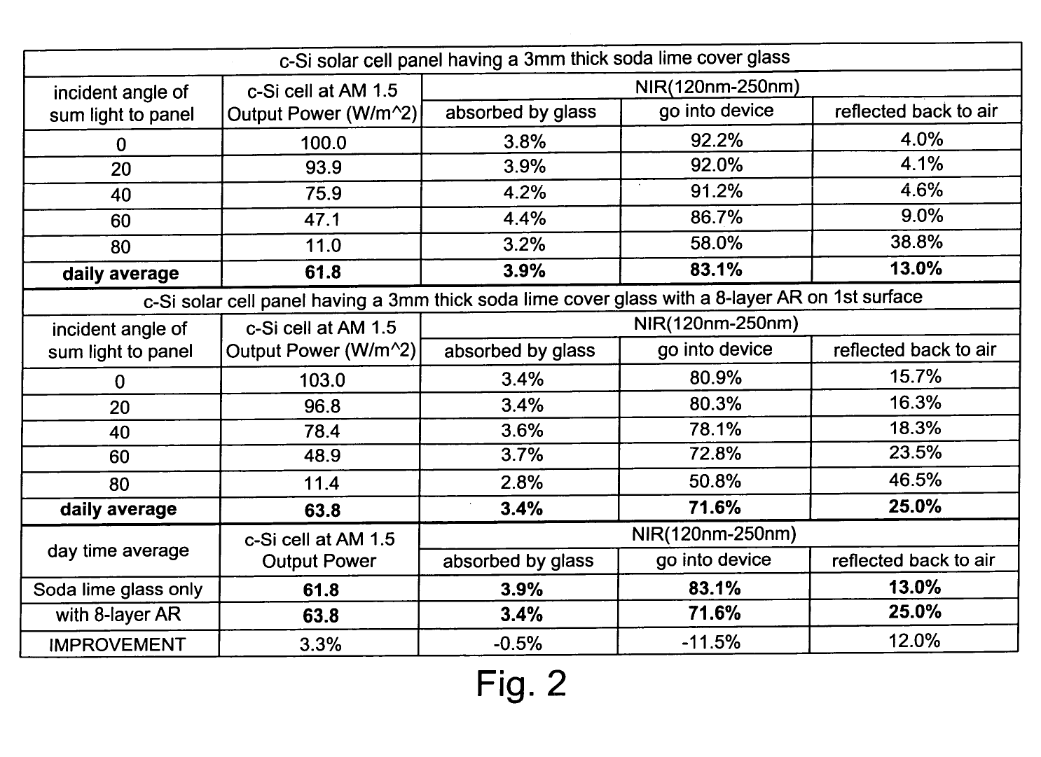

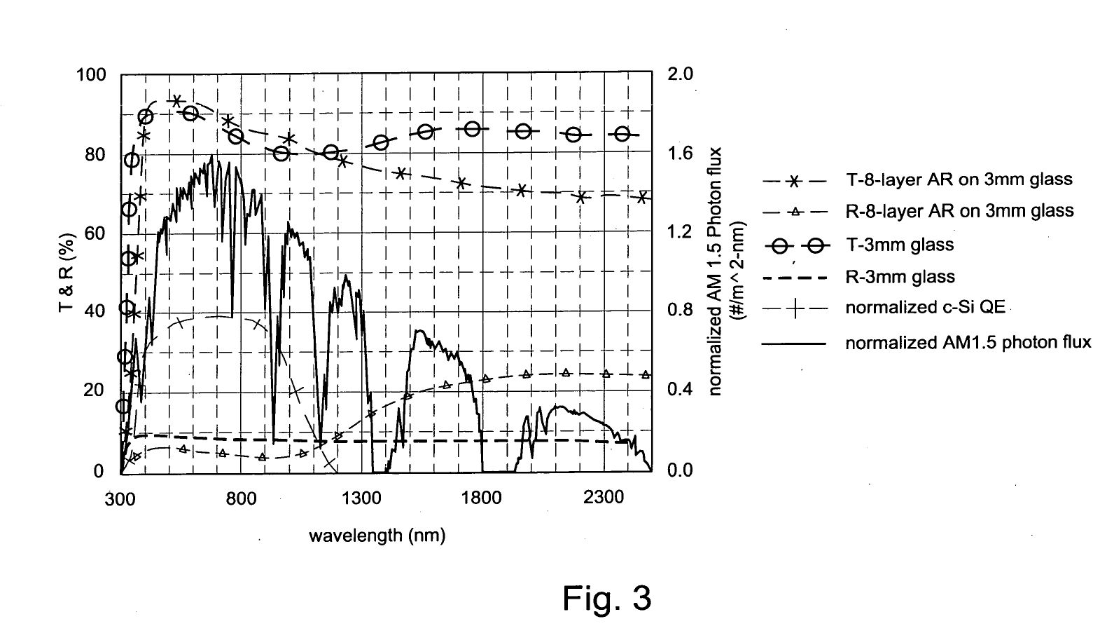

Referring to FIGS. 2-3, FIG. 3 as an example shows transmission and reflection spectra from a 3 mm thick clear soda lime glass substrate 1 with and without an example eight-layered AR coating 2 according to an example embodiment of this invention on the incident surface of the glass substrate 1. FIG. 2 sets forth data from FIG. 3. The eight-layered AR coating 2 used in the FIG. 2-3 embodiment is similar to that which is shown in FIG. 1, and includes moving from the glass substrate 1 outwardly: glass (3 nm); first TiO₂ layer 2a (13 nm thick), first SiO₂ layer 2b (40 nm thick), second TiO₂ layer 2a (31 nm thick), second SiO₂ layer 2b (13 nm thick), third TiO₂ layer 2a (94 nm thick), third SiO₂ layer 2b (18 nm thick), fourth TiO₂ layer 2a (23 nm thick), and fourth SiO₂ layer 2b (104 nm thick) as an outermost layer of the coating 2. This coating 2 was designed for the application on the exterior side of glass substrate 1 for photovoltaic applications such as single- or poly-crystal silicon, and/or other thin film solar cell panels.

In certain example embodiments, the first TiOₓ layer 2a is from about 5-50 nm thick, more preferably from about 8-30 nm thick (e.g., 13 nm thick), the first SiOₓ layer 2b is from about 10-100 nm thick, more preferably from about 20-60 nm thick (e.g., 40 nm thick), the second TiOₓ layer 2a is from about 10-70 nm thick, more preferably from about 20-40 nm thick (e.g., 31 nm thick), the second SiOₓ layer 2b is from about 5-50 nm thick, more preferably from about 8-30 nm thick (e.g., 13 nm thick), the third TiOₓ layer 2a is from about 30-150 nm thick, more preferably from about 50-110 nm thick (e.g., 94 nm thick), the third SiOₓ layer 2b is from about 5-50 nm thick, more preferably from about 10-35 nm thick (e.g., 18 nm thick), the fourth TiOₓ layer 2a is from about 10-60 nm thick, more preferably from about 12-45 nm thick (e.g., 23 nm thick), and the fourth SiOₓ layer 2b is from about 40-200 nm thick, more preferably from about 7−=140 nm thick (e.g., 104 nm thick). In certain example embodiments, first layer 2a comprising titanium oxide (closest to the glass 1) has a thickness that is less than any of the other layers 2a comprising titanium oxide. In certain example embodiments, the fourth layer comprising silicon oxide 2b farthest from the glass substrate 1 has a thickness that is greater than any of the other low index layers 2b comprising silicon oxide. In certain example embodiments, in the outermost pair of layers 2a, 2b, the low index layer 2b is substantially thicker than the high index layer 2a. In certain example embodiments, in the innermost pair of layers 2a, 2b (the pair closest to the glass 1), the low index layer 2b is substantially thicker than the high index layer 2a.

FIG. 3 illustrates that the coating 2 enhances not only the transmission overlapped with the solar cell QE and with solar radiation peak wavelengths, but also improves the reflection in undesirable wavelength ranges such as from 1300-2300 nm and/or in the near IR from 1200-3000 nm (or from 1200-2500 nm) which typically do not generate electron/hole pairs in the solar cell absorption film 5. As shown in FIGS. 2-3, the light incident into cell absorbing layer increased about 3%. The harmful UV is reduced by about 30%, and the amount of undesired heat reflected back to air is almost doubled. In other words, the overall output power from cell is improved far more than 3%. In certain example embodiments of this invention, the combination of the multi-layer coating 2 on the glass substrate 1 reflects at least about 10% of incident radiation in the range of from about 120-250 nm back into the air at a radiation incident angle(s) of one or more of 0, 20, 40 and/or 60 degrees, and even more preferably reflects at least about 12% (or even at least about 14% or 16%) of incident radiation in the range of from about 1200-2500 nm back into the air at a radiation incident angle(s) of one or more of 0, 20, 40 and/or 60 degrees (e.g., see FIG. 2). In certain example embodiments of this invention, the combination of the multi-layer coating 2 on the glass substrate 1 reflects at least about 12% of incident radiation in all of or a majority of the range of from about 1500-2500 nm back into the air at a radiation incident angle(s) of one or more of 0, 20, 40 and/or 60 degrees, and even more preferably reflects at least about 15% (or possibly at least about 20%) of incident radiation in all of or a majority of the range of from about 1500-2500 nm back into the air at a radiation incident angle(s) of one or more of 0, 20, 40 and/or 60 degrees (e.g., see FIG. 2). Thus, it can be seen that the transmission of undesirable IR and UV radiation is reduced, thereby improving performance of the photovoltaic device.

With respect to FIG. 3, the coating 2 may be designed so that its transmission and reflection were tailored to the quantum efficiency (QE) and light source spectrum (AM1.5). In particular, FIGS. 2-3 shows that the coating 2 was designed so that (a) it has a high transmission in the area under a peak area of the quantum efficiency (QE) curve of the photovoltaic device, (b) it has a high transmission in the area under a peak area of the light source spectrum (e.g., AM1.5) (note that AM1.5 refers to air mass 1.5 which represents the AM1.5 photon flux spectrum that may be used to calculate device output power), and (c) its reflection in the UV and in NIR to IR ranges are enhanced to reduce or minimize the transmission of these undesired photon energies that may be detrimental to the performance of photovoltaic devices.

In certain example embodiments of this invention, by decreasing the thickness of each or a plurality of the layers in coating 2 and/or by decreasing the index difference (e.g., by using silicon nitride or silicon aluminum nitride for one or more of the high index layers 2a instead of TiO₂), the bandwidth may be reduced to about 400-800 nm for photovoltaic devices such as a-Si single or tandem solar cells and/or CdTe photovoltaic devices.

In certain example embodiments of this invention, high transmission low-iron glass may be used for glass substrate 1 in order to further increase the transmission of radiation (e.g., photons) to the active layer of the solar cell or the like. For example and without limitation, the glass substrate 1 may be of any of the glasses described in any of U.S. Patent Document Nos. 2007/0113881 and/or 2007/0116966, and/or U.S. patent application Ser. Nos. 11/049,292 and/or 11/122,218, the disclosures of all four of which are hereby incorporated herein by reference.

It is noted that the light-incident surface of the glass substrate 1 may be flat or patterned in different example embodiments of this invention.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A photovoltaic device comprising:
a front glass substrate;
a photovoltaic semiconductor film; and
a multilayer anti-reflection coating provided on a light incident side of the front glass substrate, the anti-reflection coating comprising from the front glass substrate moving outwardly away from the semiconductor film, a first high index layer comprising an oxide of titanium, a first low index layer comprising an oxide of silicon, a second high index layer comprising an oxide of titanium, a second low index layer comprising an oxide of silicon, a third high index layer comprising an oxide of titanium, a third low index layer comprising an oxide of silicon, a fourth high index layer comprising an oxide of titanium, and a fourth low index layer comprising an oxide of silicon.

2. The photovoltaic device of claim 1, wherein the first high index layer is in direct contact with the front glass substrate.

3. The photovoltaic device of claim 1, wherein the first low index layer is substantially thicker than the first high index layer.

4. The photovoltaic device of claim 1, wherein the fourth low index layer is substantially thicker than the fourth high index layer.

5. The photovoltaic device of claim 1, wherein the fourth low index layer is thicker than any of the first, second and third low index layers.

6. The photovoltaic device of claim 1, wherein the semiconductor film comprises silicon.

7. The photovoltaic device of claim 1, wherein the anti-reflection coating on the front glass substrate reflects at least about 10% of incident radiation in the range of from about 1200-2500 nm.

8. The photovoltaic device of claim 1, wherein the anti-reflection coating on the front glass substrate reflects at least about 12% of incident radiation in the range of from about 1200-2500 nm.

9. The photovoltaic device of claim 1, wherein the anti-reflection coating on the front glass substrate reflects at least about 14% of incident radiation in the range of from about 1200-2500 nm.

10. The photovoltaic device of claim 1, wherein the anti-reflection coating has less than about 2% absorption loss in a wavelength range of from about 450 to 1100 nm.

11. The photovoltaic device of claim 1, wherein the anti-reflection coating on the front glass substrate reflects at least about 12% of incident radiation in at least a majority of a range of from about 1500-2500 nm.

12. The photovoltaic device of claim 1, wherein the anti-reflection coating on the front glass substrate reflects at least about 15% of incident radiation in at least a majority of a range of from about 1500-2500 nm.

13. A photovoltaic device comprising:
a front glass substrate;
a photovoltaic semiconductor film; and
a multilayer anti-reflection coating provided on a light incident side of the front glass substrate, the anti-reflection coating comprising from the front glass substrate moving outwardly away from the semiconductor film, a first high index layer, a first low index layer, a second high index layer, a second low index layer, a third high index layer, and a third low index layer.

14. The photovoltaic device of claim 13, wherein the anti-reflection coating further comprises a fourth high index layer and a fourth low index layer.

15. The photovoltaic device of claim 13, wherein one or more of the high index layers comprise an oxide of titanium.

16. The photovoltaic device of claim 13, wherein one or more of the high index layers comprise silicon nitride.

17. The photovoltaic device of claim 13, wherein the high index layers each have a refractive index of at least about 2.0, and the low index layers each have a refractive index of no more than about 1.7.

18. The photovoltaic device of claim 13, wherein the high index layers each have a refractive index of at least about 2.3, and the low index layers each have a refractive index of no more than about 1.6.

19. The photovoltaic device of claim 13, wherein one or more of the low index layers comprises an oxide of silicon.

20. The photovoltaic device of claim 13, wherein the anti-reflection coating on the front glass substrate reflects at least about 10% of incident radiation in the range of from about 1200-2500 nm.

21. The photovoltaic device of claim 13, wherein the anti-reflection coating on the front glass substrate reflects at least about 12% of incident radiation in the range of from about 1200-2500 nm.

22. The photovoltaic device of claim 13, wherein the anti-reflection coating on the front glass substrate reflects at least about 14% of incident radiation in the range of from about 1200-2500 nm.

23. The photovoltaic device of claim 13, wherein the anti-reflection coating has less than about 2% absorption loss in a wavelength range of from about 450 to 1100 nm.

24. The photovoltaic device of claim 13, wherein the anti-reflection coating on the front glass substrate reflects at least about 12% of incident radiation in at least a majority of a range of from about 1500-2500 nm.

25. The photovoltaic device of claim 13, wherein the anti-reflection coating on the front glass substrate reflects at least about 15% of incident radiation in at least a majority of a range of from about 1500-2500 nm.
